(19) United States
(12) Patent Application Publication
(10) Pub. No.: US 2011/0309481 A1
(43) Pub. Date: Dec. 22, 2011

(54) INTEGRATED CIRCUIT PACKAGING SYSTEM WITH FLIP CHIP MOUNTING AND METHOD OF MANUFACTURE THEREOF

(76) Inventors: Rui Huang, Singapore (SG); Seng Guan Chow, Singapore (SG); Heap Hoe Kuan, Singapore (SG)

(21) Appl. No.: 12/819,162

(22) Filed: Jun. 18, 2010

(51) Int. Cl. H01L 21/50; H01L 23/482

(52) U.S. Cl. 257/659; 438/108; 257/E21.499; 257/E23.012

(57) ABSTRACT

A method of manufacture of an integrated circuit packaging system includes: fabricating a flip chip integrated circuit die having chip interconnects on an active side; providing a substrate for coupling the flip chip integrated circuit die by the chip interconnects; and applying a conductive underfill directly on the active side to completely fill a stand-off space surrounding the chip interconnects.

### TECHNICAL FIELD

The present invention relates generally to an integrated circuit packaging system, and more particularly to a system for mounting and utilizing flip chip integrated circuits.

### BACKGROUND ART

Flip chip is a common process with which microelectronic devices, such as semiconductor devices, are electrically and mechanically coupled to a substrate, such as a circuit board, another integrated circuit, or other type of circuit carrier. In general the flip chip process allows an integrated circuit die or chip to be directly coupled to the substrate, by being placed faced down (i.e. “flipped”), having the active side of the integrated circuit facing the substrate instead of the die being placed with the active side facing up. This older “face-up” technology is commonly called wire bonding and uses metallic wires to connect to each contact pad of the substrate.

Flip chip provides an alternative to wire bonding that includes advantages in its small size, electrical performance, flexibility, reliability and cost. Flip chip is often used in smaller electronic devices such as cell phones, digital music players, personal data assistants and data storage systems. Though many high performance integrated circuits utilize flip chip attachment because of the improved electrical performance and the ability to directly attach a cooling device to the inactive side of the integrated circuit.

As the number of transistors and their switching speeds increase thermal transfer becomes a primary concern. In order to maintain the operating temperature in a range that will preserve the reliability and speed of the transistors themselves, as much heat as possible must be transferred away from the active surface of the integrated circuit as possible.

There are generally three stages to assembling a flip chip device. First, the wafer or die is selectively coated with a conductive material and heated to form bumps on the electrical contacts. Next, the bumped device is attached to the substrate by again heating the device and the conductive material. Lastly, the remaining spaces under the die are filled with a non-conductive material that strengthens the otherwise fragile connection provided by the bumped conductive material, protects the bumps and compensates for any thermal expansion difference between the die and the substrate.

Examples of different kinds of bumping include solder bumping, plated bumping, gold stud bumping and conductive adhesive bumping. The different bumping techniques provide certain advantages and disadvantages. While several of the techniques are well adjusted for volume manufacturing, their long term reliability may be suspect. This is largely due to the movement of the flip chip caused by thermal expansion and contraction.

One significant disadvantage of the flip chip is the delicate surface of the die that is exposed after it is mounted and has underfill applied. The exposed side of the die is vulnerable to mechanical damage, especially semiconductor dies which are susceptible to damage caused by the brittle nature of the elemental silicon, of which the semiconductor die is made.

Small particles of elemental silicon can emanate from mechanical damage sites that are commonly found on the edges of the exposed surface. In addition, small particles of elemental silicon can emanate from various places on the semiconductor die depending on manufacturing conditions. Regardless of how these small particles emanate from the semiconductor die, these particles can damage the electronic devices that the flip chip is positioned in.

The generation and movement of such particles is accelerated by thermal expansion of the silicon relative to the surrounding material directly in contact with the flip chip and much care is taken to match the coefficient of thermal expansion (CTE) of the material around the flip chip with the flip chip itself. The thermal excitation of the flip chip and the material surrounding it is critical to the long term reliability of the packaged device. A significant investment is made on every new combination to evaluate the long term implications of the heat generated by the flip chip and the impact of that heat on the mechanical environment in which it is placed.

Thus, a need still remains for an integrated circuit packaging system with flip chip mounting to address the thermal excitation of the packaged electronic device. In view of the demand for increased numbers of transistors and increasing clock frequencies, it is increasingly critical that answers be found to these problems. In view of the ever-increasing commercial competitive pressures, along with growing consumer expectations and the diminishing opportunities for meaningful product differentiation in the marketplace, it is critical that answers be found for these problems. Additionally, the need to reduce costs, improve efficiencies and performance, and meet competitive pressures adds an even greater urgency to the critical necessity for finding answers to these problems.

Solutions to these problems have been long sought but prior developments have not taught or suggested any solutions and, thus, solutions to these problems have long eluded those skilled in the art.

### DISCLOSURE OF THE INVENTION

The present invention provides a method of manufacture of an integrated circuit packaging system including: fabricating a flip chip integrated circuit die having chip interconnects on an active side; providing a substrate for coupling the flip chip integrated circuit die by the chip interconnects; and applying a conductive underfill directly on the active side to completely fill a stand-off space surrounding the chip interconnects.

The present invention provides an integrated circuit packaging system, including: a flip chip integrated circuit die having chip interconnects on an active side; a conductive underfill directly on the active side to completely fill a stand-off space around the chip interconnects; and a substrate coupled to the flip chip integrated circuit die by the chip interconnects.

Certain embodiments of the invention have other steps or elements in addition to or in place of those mentioned above. The steps or element will become apparent to those skilled in the art from a reading of the following detailed description when taken with reference to the accompanying drawings.

### BRIEF DESCRIPTION OF THE DRAWINGS

FIG. 1 is a cross-sectional view of an integrated circuit packaging system with flip chip mounting in a first embodiment of the present invention.

FIG. 2 is an enlarged cross-sectional view of a chip interconnect interface between the flip chip integrated circuit die and the substrate in the first embodiment of the present invention.

FIG. 3 is an enlarged cross-sectional view of a chip interconnect interface between the flip chip integrated circuit die and the substrate in an alternative embodiment of FIG. 2.

FIG. 4 is a cross-sectional view of an integrated circuit packaging system in a die attach phase of manufacturing.

FIG. 5 is a cross-sectional view of an integrated circuit packaging system in an underfill application phase of manufacturing.

FIG. 6 is a cross-sectional view of an integrated circuit packaging system with flip chip mounting in a second embodiment of the present invention.

FIG. 7 is a cross-sectional view of a semiconductor wafer in a chip interconnect coating phase of manufacturing.

FIG. 8 is a cross-sectional view of a semiconductor wafer assembly in a planarization phase of manufacturing.

FIG. 9 is a cross-sectional view of an integrated circuit packaging system in a die attach phase of manufacturing.

FIG. 10 is a cross-sectional view of an integrated circuit packaging system in an underfill application phase of manufacturing.

FIG. 11 is a cross-sectional view of an integrated circuit packaging system with flip chip mounting in a third embodiment of the present invention.

FIG. 12 is a flow chart of a method of manufacture of the integrated circuit packaging system in a further embodiment of the present invention.

### BEST MODE FOR CARRYING OUT THE INVENTION

The following embodiments are described in sufficient detail to enable those skilled in the art to make and use the invention. It is to be understood that other embodiments would be evident based on the present disclosure, and that system, process, or mechanical changes may be made without departing from the scope of the present invention.

In the following description, numerous specific details are given to provide a thorough understanding of the invention. However, it will be apparent that the invention may be practiced without these specific details. In order to avoid obscuring the present invention, some well-known circuits, system configurations, and process steps are not disclosed in detail.

The drawings showing embodiments of the system are semi-diagrammatic and not to scale and, particularly, some of the dimensions are for the clarity of presentation and are shown exaggerated in the drawing FIGs. Similarly, although the views in the drawings for ease of description generally show similar orientations, this depiction in the FIGs. is arbitrary for the most part. Generally, the invention can be operated in any orientation.

Where multiple embodiments are disclosed and described having some features in common, for clarity and ease of illustration, description, and comprehension thereof, similar and like features one to another will ordinarily be described with similar reference numerals. The embodiments have been numbered first embodiment, second embodiment, etc. as a matter of descriptive convenience and are not intended to have any other significance or provide limitations for the present invention.

For expository purposes, the term “horizontal” as used herein is defined as a plane parallel to the plane or surface of the integrated circuit die, regardless of its orientation. The term “vertical” refers to a direction perpendicular to the horizontal as just defined. Terms, such as “above”, “below”, “bottom”, “top”, “side” (as in “sidewall”), “higher”, “lower”, “upper”, “over”, and “under”, are defined with respect to the horizontal plane, as shown in the figures. The term “on” means that there is direct contact between elements without having intervening materials.

The term “processing” as used herein includes deposition of material or photoresist, patterning, exposure, development, etching, cleaning, and/or removal of the material or photoresist as required in forming a described structure.

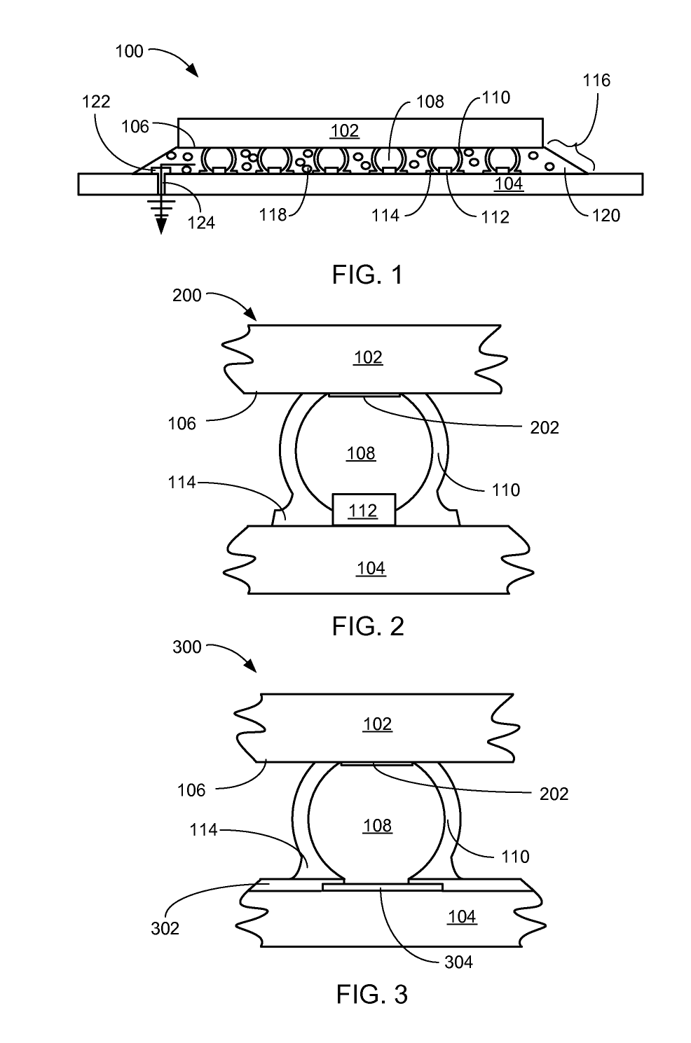

Referring now to FIG. 1, therein is shown a cross-sectional view of an integrated circuit packaging system 100 with flip chip mounting in a first embodiment of the present invention. The cross-sectional view of the integrated circuit packaging system 100 depicts a flip chip integrated circuit die 102 coupled to a substrate 104, such as a laminate substrate, a semiconductor substrate, or an integrated circuit die.

The flip chip integrated circuit die 102 may have an active side 106 facing the substrate 104. The active side 106 is the primary source of heat generated by the flip chip integrated circuit die 102, as the transistors and passive components that form circuits on the flip chip integrated circuit die 102, are fabricated on that side.

As is known in the art, the removal of the heat generated by the circuits of the flip chip integrated circuit die 102 is a significant issue. Also as is known in the art the silicon wafer, on which the circuits of the flip chip integrated circuit die 102 are formed, is not a good conductor of the heat generated on its surface.

Chip interconnects 108, such as solder bumps, solder columns, solder balls, stud bumps, or metal bumps, are formed on the active side 106 for making an electrical connection to the substrate 104. The chip interconnects 108 have an insulative coating 110 formed to enclose the electrical connection made by the chip interconnects 108. Substrate contacts 112, such as metal traces, solder caps, gold stud bumps, copper pillars, or copper bumps, may be electrically connected to circuitry in the substrate or beyond the substrate in the next level system (not shown).

The insulative coating 110 may include a penetrable polymeric material, such as epoxies or polyimide, applied on the chip interconnects 108. The penetrable polymeric material may have a thickness in the range of 1-10 micron on the surface of the chip interconnects 108. The insulative coating 110 may be partially cured to a B-stage state, which leaves the coating penetrable for further electrical connection.

The insulative coating 110 may form a collar 114 around the substrate contacts 112 to completely isolate the electrical connection between the flip chip integrated circuit die 102 and the substrate contacts 112. A conductive underfill 116, is both thermally conductive and electrically conductive. The conductive underfill 116 may be optimized for thermal transfer by suspending electrically conductive particles 118, such as particles of nickel coated graphite, silver plated glass, silver plated copper, silver plated aluminum, or suspended metals such as silver, magnesium, iron, zirconium, cobalt, or copper, in a polymer base material 120.

The conductive underfill 116 may completely fill the space between the flip chip integrated circuit die 102 and the substrate 104 to completely enclose the insulative coating 110. A ground terminal 122 may be formed on the surface of the substrate 104 and may also have the conductive underfill 116 deposited directly thereon.

It has been discovered that the conductive underfill 116, having a weight percentage of the electrically conductive particles 118 in the range of 70-95%, provides a significant increase in the heat transfer between the flip chip integrated circuit die 102 and the substrate 104. Another beneficial aspect of the present invention is that the heat is now distributed evenly across the surface of the flip chip integrated circuit die 102 rather than concentrated at the chip interconnects 108 as in prior art implementations. It has also been discovered that the present invention may reduce or prevent cracks in Low-K and Ultra Low-K dielectric layers, used in the interconnect structure, by reducing hot spots around the chip interconnects 108.

In prior art structures, the chip interconnects 108 may provide the primary heat transfer path, which causes hot spots around and through the chip interconnects 108 as the heat converges there. The convergence of the heat at the chip interconnects 108, in the prior art structures, was a primary source of reliability issued due to thermal expansion that could crack or damage the chip interconnects 108 and apply additional thermal stress to the circuitry in the vicinity of the chip interconnects 108.

The present invention provides an evenly distributed transfer of generated heat without concentrating the heat at the chip interconnects 108, thus reducing the thermal stress on the electrical connections and improving the long term reliability of the flip chip integrated circuit die 102. The circuitry in the vicinity of the chip interconnects 108 is also subject to less thermal stress as the local concentration of heat is reduced as compared to the prior art structures.

It has also been discovered that the addition of the ground terminal 122 on the surface of the substrate 104 may provide an electrical reference for the conductive underfill 116. This electrical reference will provide an electro-magnetic interface (EMI) shield to block radiated energy, or cross-talk, from the chip interconnects 108 or other sources on the substrate 104. The conductive underfill coupled through the ground terminal 122 may shield the circuits on the flip chip integrated circuit die 102 and improve their electrical performance due to reduced electrical noise from radiated sources.

The substrate 104 may have a through via 124 for coupling the ground terminal 122 to other layers within the substrate 104 or for coupling to the next level system. It is understood that the ground reference symbol is for clarity only and is not present in the implementation of the present invention. It is also understood that the line and arrow extending through the ground terminal 122 and the through via 124 is intended to show the direction of current flow from the conductive underfill 116 and is for reference only.

The number and distribution of the electrically conductive particles 118 is for clarity and example. The actual distribution of the electrically conductive particles 118 is far more extensive.

Thus, it has been discovered that the integrated circuit packaging system and device of the present invention furnishes important and heretofore unknown and unavailable solutions, capabilities, and functional aspects for providing a flip chip mounting process and mechanism that increases reliability of the electronic device and enhances the performance of the packaged device.

Referring now to FIG. 2, therein is shown an enlarged cross-sectional view of a chip interconnect interface 200 between the flip chip integrated circuit die 102 and the substrate 104 in the first embodiment of the present invention. The enlarged cross-sectional view of the chip interconnect interface 200 depicts the flip chip integrated circuit die 102 having a chip contact 202 on the active side 106 with the chip interconnect 108 coupled thereto.

The insulative coating 110 may be displaced by the substrate contact 112 when the flip chip integrated circuit die 102 is mounted on the substrate 104. The collar 114 may be completely formed around the substrate contact 112 when the chip interconnect 108 goes through the reflow process to establish the electrical connection between the flip chip integrated circuit die 102 and the substrate 104. While the collar 114 is shown to extend beyond the diameter of the chip interconnect 108, this is an example only for clarity and the actual may differ. The combination of the insulative coating 110 and the collar 114 completely encloses the chip contact 202, the chip interconnect 108 and the substrate contact 112, forming an insulation barrier around the electrical connection.

Referring now to FIG. 3, therein is shown an enlarged cross-sectional view of a chip interconnect interface 300 between the flip chip integrated circuit die 102 and the substrate 104 in an alternative embodiment of FIG. 2. The enlarged cross-sectional view of the chip interconnect interface 300 depicts the flip chip integrated circuit die 102 having the chip contact 202 on the active side 106 with the chip interconnect 108 coupled thereto.

The insulative coating 110 may be displaced across a solder mask layer 302 when the flip chip integrated circuit die 102 is mounted on the substrate 104. The collar 114 may be completely formed around a solder mask defined contact 304 when the chip interconnect 108 goes through the reflow process to establish the electrical connection between the flip chip integrated circuit die 102 and the substrate 104. While the collar 114 is shown to extend beyond the diameter of the chip interconnect 108, this is an example only for clarity and the actual may differ. The combination of the insulative coating 110 and the collar 114 completely encloses the chip contact 202, the chip interconnect 108 and the solder mask defined contact 304, forming an insulation barrier around the electrical connection.

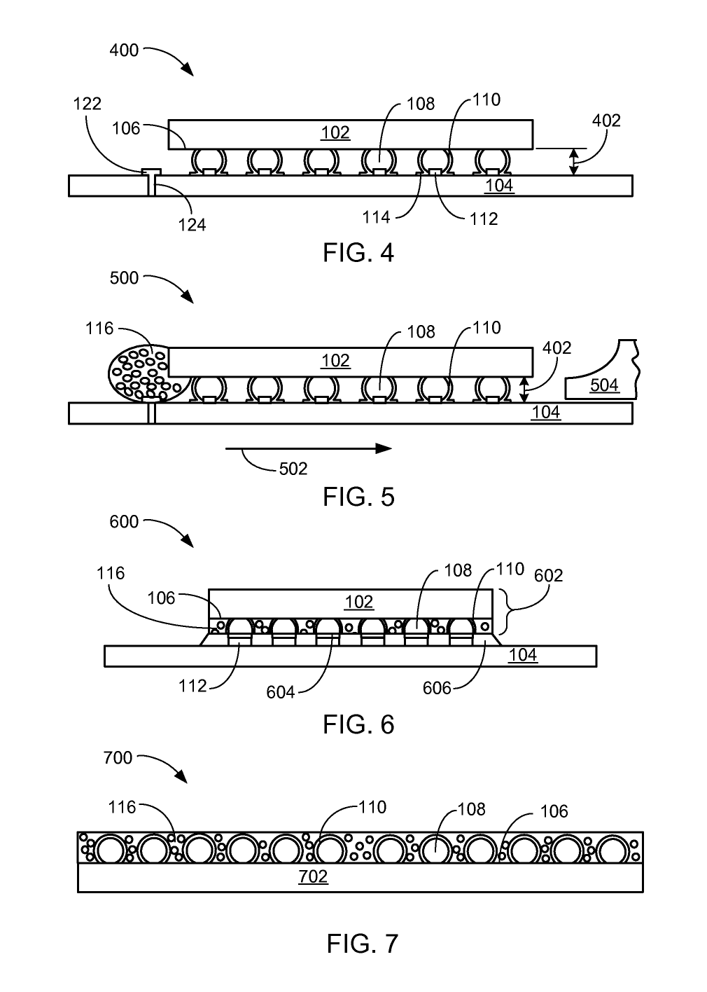

Referring now to FIG. 4, therein is shown a cross-sectional view of an integrated circuit packaging system 400 in a die attach phase of manufacturing. The cross-sectional view of the integrated circuit packaging system 400 depicts the flip chip integrated circuit die 102 coupled to the substrate 104, such as a printed circuit board, a semiconductor substrate, or an integrated circuit die.

The flip chip integrated circuit die 102 may have the active side 106 facing the substrate 104. The active side 106 is the primary source of heat generated by the flip chip integrated circuit die 102 while in operation. As the transistors and passive components that form circuits on the flip chip integrated circuit die 102 are fabricated on the active side 106, generated heat is most intense across the active side 106.

The chip interconnects 108 are formed on the active side 106 for making an electrical connection to the substrate 104. The chip interconnects 108 have the insulative coating 110 formed to enclose the electrical connection made by the chip interconnects 108. The substrate contacts 112, such as metal traces, solder caps, gold stud bumps, copper pillars, or copper bumps, may be electrically connected to circuitry in the substrate or beyond the substrate in the next level system (not shown).

The chip interconnects 108 provide a stand-off space 402 between the flip chip integrated circuit die 102 and the opposing side of the chip interconnects 108. The stand-off space 402 may be the same as the space between the flip chip integrated circuit die 102 and the substrate 104. The stand-off space 402 is well controlled by the manufacturing process and the volume of the stand-off space 402 is well known in the manufacturing process.

The insulative coating 110 may include a polymeric material, such as epoxies or polyimide, applied on the chip interconnects 108. The polymeric material may have a thickness in the range of 1-10 micron on the surface of the chip interconnects 108. The insulative coating 110 may be partially cured to a B-stage state, which leaves the coating penetrable for further electrical connection.

The insulative coating 110 may form the collar 114 around the substrate contacts 112 to completely isolate the electrical connection between the flip chip integrated circuit die 102 and the substrate contacts 112. The ground terminal 122 on the surface of the substrate 104 may provide an electrical reference. The substrate 104 may have the through via 124 for coupling the ground terminal 122 to other layers within the substrate 104 or for coupling to the next level system.

Referring now to FIG. 5, therein is shown a cross-sectional view of an integrated circuit packaging system 500 in an underfill application phase of manufacturing. The cross-sectional view of the integrated circuit packaging system 500 depicts the flip chip integrated circuit die 102 coupled to the substrate 104 by the chip interconnects 108.

The conductive underfill 116 may be applied at an edge of the flip chip integrated circuit die 102. The conductive underfill 116 may be drawn into the stand-off space 402 to surround the chip interconnects 108, having the insulative coating 110, by an applied magnetic field 502, a vacuum 504 applied at the opposing edge of the flip chip integrated circuit die 102, or a combination thereof.

It has been discovered that the application of the conductive underfill 116 in the presence of the combination of the magnetic field 502 and the vacuum 504 may reduce the manufacturing cycle time and allow the conductive underfill 116 may be precisely positioned in the stand-off space 402 with a clearly defined underfill stop line. In a final step the conductive underfill 116 will be fully cured in order to prevent additional migration from beneath the flip chip integrated circuit die 102.

Referring now to FIG. 6, therein is shown a cross-sectional view of an integrated circuit packaging system 600 with flip chip mounting in a second embodiment of the present invention. The cross-sectional view of the integrated circuit packaging system 600 depicts a flip chip die assembly 602 mounted over the substrate 104.

The flip chip die assembly 602 may include a portion of the chip interconnects 108 coupled to the flip chip integrated circuit die 102. The portion of the chip interconnects 108 is coated on the sides by the insulative coating 110. A layer of the conductive underfill is formed on the insulative coating 110 to surround the sides of the portion of the chip interconnects 108.

The substrate 104 may have the substrate contacts 112 on a top surface, facing the flip chip die assembly 602. A solder cap 604 may be formed on the substrate contacts 112 for coupling to an exposed surface of the portion of the chip interconnects 108.

An insulating underfill 606 may be applied in the gap between the substrate 104 and the flip chip die assembly 602. The insulating underfill 606 may be dispended as a fluid or applied as a no-flow film.

It has been discovered that the insulative underfill 606 may absorb the thermal stresses caused by the transfer of the generated heat through the active side 106. When used in conjunction with the conductive underfill 116 of the flip chip die assembly 602 the convergence of heat may occur in the conductive underfill 116 rather than in the circuitry surrounding the chip interconnects 108. This process may reduce the thermal stress associated with the circuitry on the active side of the flip chip integrated circuit die 102 and enhance the overall reliability.

Referring now to FIG. 7, therein is shown a cross-sectional view of a semiconductor wafer 700 in a chip interconnect coating phase of manufacturing. The cross-sectional view of the semiconductor wafer 700 depicts a semiconductor wafer 702 having multiple copies of the flip chip integrated circuit die 102, of FIG. 1.

The chip interconnects 108 may be coupled to the active side 106 of the semiconductor wafer 702. Each of the chip interconnects 108 may be completely enclosed by a layer of the insulative coating 110. The insulative coating may be conformed to the chip interconnects 108 in a layer that is in the range of 1-10 micron thick.

A layer of the conductive underfill 116 may completely encapsulate the insulative coating 110 and the active side 106 of the semiconductor wafer 702. In some implementations the conductive underfill 116 may just enclose the top of the insulative coating 110.

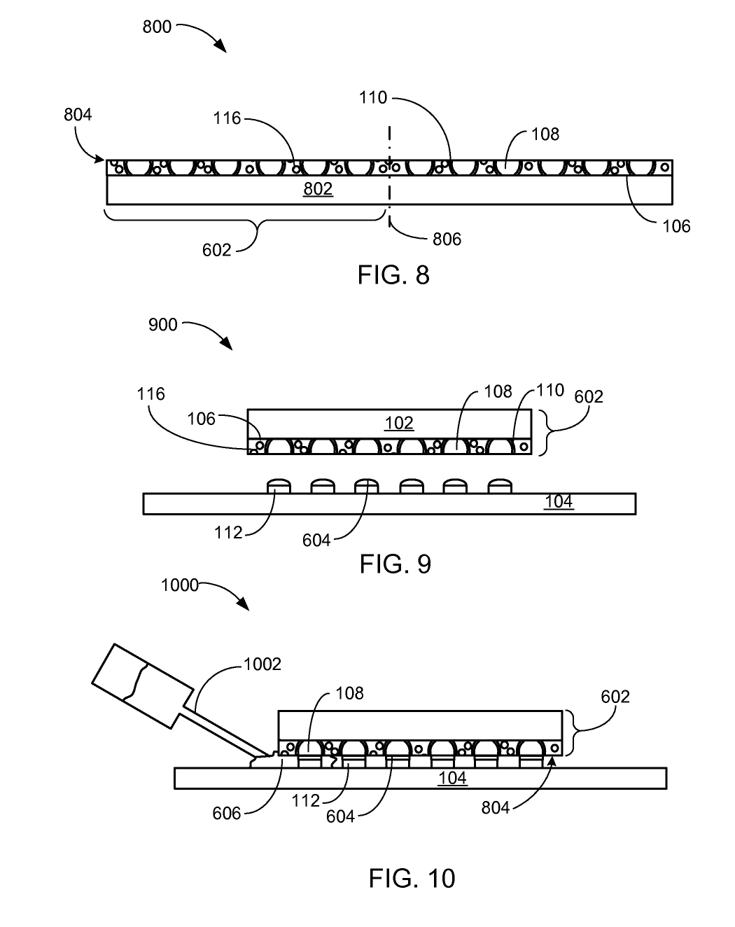

Referring now to FIG. 8, therein is shown a cross-sectional view of a semiconductor wafer assembly 800 in a planarization phase of manufacturing. The cross-sectional view of the semiconductor wafer assembly 800 depicts a semiconductor wafer 802 having multiple copies of the flip chip integrated circuit die 102, of FIG. 1.

The chip interconnects 108 may be coupled to the active side 106 of the semiconductor wafer 802. Each of the chip interconnects 108 may be completely enclosed by a layer of the insulative coating 110. The insulative coating may be conformed to the chip interconnects 108 in a layer that is in the range of 1-10 micron thick.

A layer of the conductive underfill 116 may completely encapsulate the insulative coating 110 and the active side 106 of the semiconductor wafer 802. A planar surface 804 may comprise the conductive underfill 116 having the portions of the chip interconnects 108 distributed thereon with the insulative coating 110 separating the chip interconnects 108 from the conductive underfill 116.

The planar surface 804 may be formed by chemical-mechanical planarization, milling, or grinding. A singulation line 806 may indicate a location where the semiconductor wafer 802 will be divided by sawing or shearing to separate each of the flip chip die assembly 602.

Referring now to FIG. 9, therein is shown a cross-sectional view of an integrated circuit packaging system 900 in a die attach phase of manufacturing. The a cross-sectional view of the integrated circuit packaging system 900 depicts the flip chip die assembly 602 having been singulated from the semiconductor wafer assembly 800, of FIG. 8.

The substrate 104 may have the substrate contacts 112 fabricated on the side facing the flip chip die assembly 602. The substrate contacts 112 may provide an electrical interface to the circuitry of the substrate 104. The substrate contacts 112 may have the solder cap 604 formed on a surface facing the flip chip die assembly 602. The size of the substrate contacts 112 and the solder cap 604 may be smaller than the diameter of the portion of the chip interconnect 108 in order to prevent inadvertent connection to the conductive underfill 116.

It has been discovered that the coupling of the substrate contact 112, having a slightly larger diameter may be used to couple the reference voltage to the conductive underfill 116 for providing the shielding aspect of the present invention.

Referring now to FIG. 10, therein is shown a cross-sectional view of an integrated circuit packaging system 1000 in an underfill application phase of manufacturing. The cross-sectional view of the integrated circuit packaging system 1000 depicts the flip chip die assembly 602 having been electrically connected to the substrate 104 by coupling the solder cap 604 to the portion of the chip interconnects 108.

An applicator 1002 may apply the insulating underfill 606 between the surface of the substrate 104 and the planar surface 804 of the flip chip die assembly 602 to completely surround the substrate contacts 112 and the solder caps 604. It is understood that the application of the insulating underfill 606 as a fluid is an example only and the insulating underfill 606 may be applied as a no-flow film or sheet.

The insulating underfill 606 may provide a compliant support layer for absorbing the stress of thermal expansion in the system. The presence of the insulating underfill 606 may reduce the stress of the substrate contact 112 relative to the circuitry of the substrate 104.

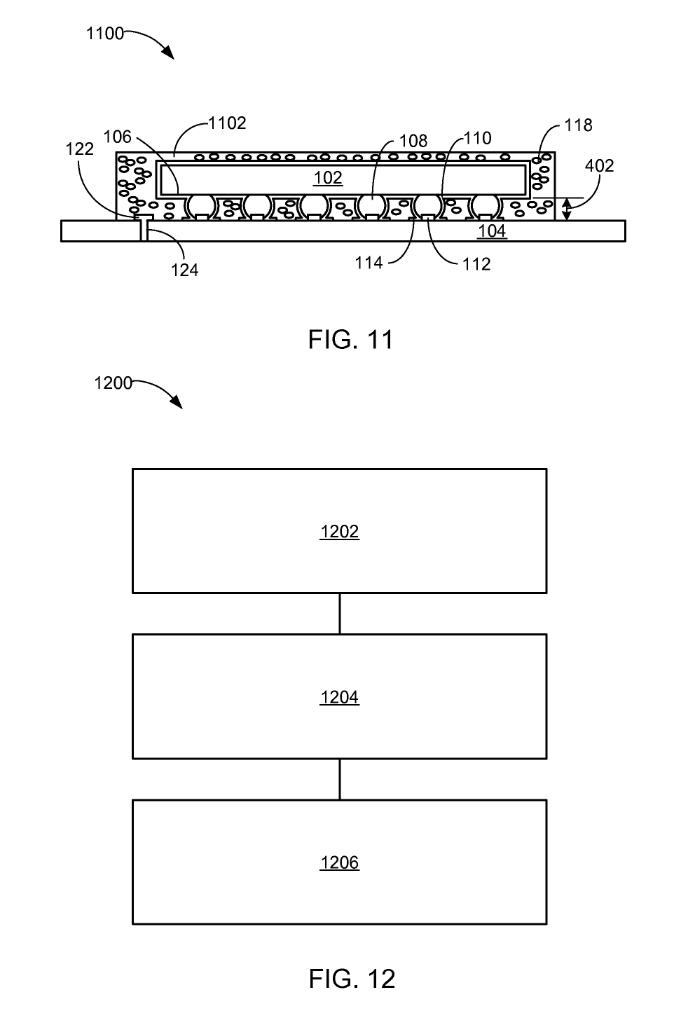

Referring now to FIG. 11, therein is shown a cross-sectional view of an integrated circuit packaging system 1100 with flip chip mounting in a third embodiment of the present invention. The cross-sectional view of the integrated circuit packaging system 1100 depicts the flip chip integrated circuit die 102 coupled to the substrate 104, such as a printed circuit board, a semiconductor substrate, or an integrated circuit die.

The flip chip integrated circuit die 102 may have the active side 106 facing the substrate 104. The active side 106 is the primary source of heat generated by the flip chip integrated circuit die 102 while in operation. As the transistors and passive components that form circuits on the flip chip integrated circuit die 102 are fabricated on the active side 106, generated heat is most intense across the active side 106.

The chip interconnects 108 are formed on the active side 106 for making an electrical connection to the substrate 104. The insulative coating 110 formed to enclose the electrical connection made by the chip interconnects 108 may completely enclose the flip chip integrated circuit die 102. The substrate contacts 112, such as metal traces, solder caps, gold stud bumps, copper pillars, or copper bumps, may be electrically connected to circuitry in the substrate or beyond the substrate in the next level system (not shown).

The chip interconnects 108 provide the stand-off space 402 between the insulative coating 110 formed on the flip chip integrated circuit die 102 and the opposing side of the chip interconnects 108. The stand-off space 402 may be the same as the space between the insulative coating 110 formed on the flip chip integrated circuit die 102 and the substrate 104. The stand-off space 402 is well controlled by the manufacturing process and the volume of the stand-off space 402 is well known in the manufacturing process.

The insulative coating 110 may include a polymeric material, such as epoxies or polyimide, applied on flip chip integrated circuit die 102 and the chip interconnects 108. The polymeric material may have a thickness in the range of 1-10 micron on the surface of the chip interconnects 108. The insulative coating 110 may be partially cured to a B-stage state, which leaves the coating penetrable for further electrical connection.

The insulative coating 110 may form the collar 114 around the substrate contacts 112 to completely isolate the electrical connection between the flip chip integrated circuit die 102 and the substrate contacts 112. The ground terminal 122 on the surface of the substrate 104 may provide an electrical reference. The substrate 104 may have the through via 124 for coupling the ground terminal 122 to other layers within the substrate 104 or for coupling to the next level system.

A conductive molded underfill (MUF) 1102, having the electrically conductive particles 118, may completely enclose the insulative coating 110. By encapsulating the ground terminal 122 within the conductive molded underfill 1102, an electromagnetic shield may be formed to completely surround the flip chip integrated circuit die 102 including the active side 106.

It has been discovered that insulative coating 110, having completely isolated the flip chip integrated circuit die 102, may provide the fourth embodiment of the present invention. The use of the conductive molded underfill (MUF) 1102 to encapsulate the flip chip integrated circuit die 102, may provide a thermal solution to prevent cracking in low-K and ultra-low-K dielectric layers. It is understood that additional applications of the insulative coating 110 may be required to isolate all of the electrical connections of the flip chip integrated circuit die 102 prior to applying the conductive molding compound. It is also understood that the insulative coating 110 may be fully cured prior to forming the conductive molded underfill 1102.

Referring now to FIG. 12, therein is shown a flow chart of a method 1200 of manufacture of the integrated circuit packaging system 100 in a further embodiment of the present invention. The method 1200 includes: fabricating a flip chip integrated circuit die having chip interconnects on an active side in a block 1202; providing a substrate for coupling the flip chip integrated circuit die by the chip interconnects in a block 1204; and applying a conductive underfill directly on the active side to completely fill a stand-off space surrounding the chip interconnects in a block 1206.

The resulting method, process, apparatus, device, product, and/or system is straightforward, cost-effective, uncomplicated, highly versatile and effective, can be surprisingly and unobviously implemented by adapting known technologies, and are thus readily suited for efficiently and economically manufacturing flip chip integrated circuit device systems fully compatible with conventional manufacturing methods or processes and technologies.

Another important aspect of the present invention is that it valuably supports and services the historical trend of reducing costs, simplifying systems, and increasing performance.

These and other valuable aspects of the present invention consequently further the state of the technology to at least the next level.

While the invention has been described in conjunction with a specific best mode, it is to be understood that many alternatives, modifications, and variations will be apparent to those skilled in the art in light of the aforegoing description. Accordingly, it is intended to embrace all such alternatives, modifications, and variations that fall within the scope of the included claims. All matters hithertofore set forth herein or shown in the accompanying drawings are to be interpreted in an illustrative and non-limiting sense.

What is claimed is:

1. A method of manufacture of an integrated circuit packaging system comprising:
fabricating a flip chip integrated circuit die having chip interconnects on an active side;
providing a substrate for coupling the flip chip integrated circuit die by the chip interconnects; and
applying a conductive underfill directly on the active side to completely fill a stand-off space surrounding the chip interconnects.

2. The method as claimed in claim 1 further comprising applying an insulative coating on the chip interconnects.

3. The method as claimed in claim 1 further comprising providing a ground terminal in the substrate having the conductive underfill applied thereon.

4. The method as claimed in claim 1 wherein applying the conductive underfill includes applying a magnetic field for positioning the conductive underfill or molding a conductive molded underfill to encapsulate the flip chip integrated circuit die.

5. The method as claimed in claim 1 wherein applying the conductive underfill includes:
applying an insulative coating between the chip interconnects and the conductive underfill;
forming a planar surface having the conductive underfill, the insulative coating and the chip interconnects thereon; and
coupling substrate contacts, of the substrate, to the chip interconnects.

6. A method of manufacture of an integrated circuit packaging system comprising:
fabricating a flip chip integrated circuit die having chip interconnects on an active side;
providing a substrate for coupling the flip chip integrated circuit die by the chip interconnects in which the substrate includes a laminate substrate, a semiconductor substrate, or an integrated circuit; and
applying a conductive underfill directly on the active side to completely fill a stand-off space surrounding the chip interconnects including applying electrically conductive particles in the conductive underfill.

7. The method as claimed in claim 6 further comprising applying an insulative coating on the chip interconnects wherein applying the insulative coating includes applying a penetrable polymeric material, including epoxy or polyimide.

8. The method as claimed in claim 6 further comprising providing a ground terminal in the substrate having the conductive underfill applied thereon including forming an electro-magnetic interference shield.

9. The method as claimed in claim 6 wherein applying the conductive underfill includes applying a magnetic field for positioning the conductive underfill including using a vacuum, the magnetic field, or a combination thereof or molding a conductive molded underfill to encapsulate the flip chip integrated circuit die.

10. The method as claimed in claim 6 wherein applying the conductive underfill includes:
applying an insulative coating between the chip interconnects and the conductive underfill;
forming a planar surface having the conductive underfill, the insulative coating and the chip interconnects thereon in which forming the planar surface by chemical-mechanical planarization, milling, or grinding; and
coupling substrate contacts, of the substrate, to the chip interconnects including applying an insulating underfill between the substrate and the planar surface for absorbing thermal stress.

11. An integrated circuit packaging system comprising:
a flip chip integrated circuit die having chip interconnects on an active side;
a conductive underfill directly on the active side to completely fill a stand-off space around the chip interconnects; and
a substrate coupled to the flip chip integrated circuit die by the chip interconnects.

12. The system as claimed in claim 11 further comprising an insulative coating on the chip interconnects.

13. The system as claimed in claim 11 further comprising a ground terminal in the substrate with the conductive underfill applied thereon including a conductive molded underfill encapsulating the flip chip integrated circuit die and the ground terminal.

14. The system as claimed in claim 11 wherein the conductive underfill includes electrically conductive particles.

15. The system as claimed in claim 11 further comprising a flip chip die assembly coupled to the substrate including:
a planar surface includes the conductive underfill, the chip interconnects, and an insulative coating between the chip interconnects and the conductive underfill;
substrate contacts, on the substrate, coupled to the chip interconnects in the planar surface; and
an insulating underfill contacts the planar surface and the substrate to enclose the substrate contacts.

16. The system as claimed in claim 11 further comprising:
a laminate substrate, a semiconductor substrate, or an integrated circuit is the substrate; and
electrically conductive particles in the conductive underfill.

17. The system as claimed in claim 16 further comprising an insulative coating on the chip interconnects includes a penetrable polymeric material, including a B-stage epoxy or polyimide.

18. The system as claimed in claim 16 further comprising a ground terminal in the substrate with the conductive underfill applied thereon including a conductive molded underfill encapsulating the flip chip integrated circuit die and the ground terminal includes an electro-magnetic interference shield formed on the active side.

19. The system as claimed in claim 16 further comprising:
a substrate contact on the substrate; and
a collar, formed by an insulative coating, encloses the substrate contact.

20. The system as claimed in claim 16 further comprising a flip chip die assembly coupled to the substrate including:
a planar surface includes the conductive underfill, the chip interconnects, and an insulative coating between the chip interconnects and the conductive underfill;
substrate contacts, on the substrate, coupled to the chip interconnects in the planar surface by solder caps; and
an insulating underfill contacts the planar surface and the substrate to enclose the substrate contacts and the solder caps.
